(19) United States
(12) Patent Application Publication
(10) Pub. No.: US 2012/0274338 A1
(43) Pub. Date: Nov. 1, 2012

(54) HIGH PERFORMANCE TIME DOMAIN REFLECTOMETRY

(75) Inventors: Christian W. Baks, Poughkeepsie, NY (US); Richard A. John, Yorktown Heights, NY (US); Young H. Kwark, Chappaqua, NY (US)

(73) Assignee: INTERNATIONAL BUSINESS MACHINES CORPORATION, Armonk, NY (US)

(21) Appl. No.: 13/097,595

(22) Filed: Apr. 29, 2011

(51) Int. Cl. G01R 27/28; G01R 1/06

(52) U.S. Cl. 324/617; 324/149

(57) ABSTRACT

Methods and systems for high-bandwidth time domain reflectometry include a printed circuit board (PCB) and a probe. The PCB includes at least one signal terminal connected to at least one signal via at least three guide terminals arranged around the at least one high-frequency signal terminal. At least one of the guide terminals is connected to at least one ground via. The probe includes at least one biased pin to contact the at least one signal terminal and at least three fixed guide pins arranged about the at least one biased pin to facilitate alignment of said at least one biased pin by first engaging at least one guide terminal area, such that the at least one mechanically biased pin is guided to the at least one contact point.

### GOVERNMENT RIGHTS

This invention was made with Government support under Contract No.: HR0011-07-9-0002 awarded by Defense Advanced Research Projects Agency. The Government has certain rights to this invention.

### BACKGROUND

1. Technical Field

The present invention relates to time domain reflectometry and, in particular, to systems for high performance time domain reflectometry using a tripod stabilized probe configuration.

2. Description of the Related Art

Line impedance is a key parameter of fabricated high speed transmission lines in printed circuit boards (PCBs). Time Domain Reflectometry (TDR) is often used to measure impedance using relatively simple test equipment. If this impedance differs from the impedance of other elements connected by these transmission lines, reflections will occur which can lead to errors in data communication. As communications speeds on PCBs has increased, impedance information is now needed at much higher frequencies, and while fast TDR step generator units are readily available, launching a very fast edge onto PCB traces is limited by existing TDR probes and TDR launch construction.

### SUMMARY

A probe is shown that includes at least one mechanically biased pin to connect to at least one contact point and at least three fixed guide pins arranged about the at least one biased pin to facilitate alignment of said at least one biased pin by first engaging at least one grounded area, such that the at least one mechanically biased pin is guided to the at least one contact point.

A high-speed probe launch is shown that includes a printed circuit board (PCB) configured to provide access to a probe. The PCB includes at least one signal terminal connected to at least one signal via and at least three guide terminals arranged around the at least one signal terminal, wherein at least one of said guide terminals is connected to at least one ground via.

A time domain reflectometry system is shown that includes a PCB and a probe. The PCB includes at least one signal terminal connected to at least one signal via and at least three guide terminals arranged around the at least one high-frequency signal terminal, wherein at least one of said guide terminals is connected to at least one ground via. The probe includes at least one biased pin to contact the at least one signal terminal and at least three fixed guide pins arranged about the at least one biased pin to facilitate alignment of said at least one biased pin by first engaging at least one guide terminal area, such that the at least one mechanically biased pin is guided to the at least one contact point.

A high bandwidth time domain reflectometry system is shown that include a PCB and a probe. The PCB includes at least one high-frequency signal terminal; and at least three ground terminals arranged around the at least one high-frequency signal terminal. The probe includes at least one spring-loaded pin to contact signal vias and at least three grounding fixed pins having conical tips formed arranged about the at least one spring-loaded pin to facilitate alignment of said spring-loaded pins and to provide mechanical stability.

A method for time domain reflectometry (TDR) is shown that includes providing a TDR probe having at least one biased pin and at least three fixed guide pins to correspond to at least one signal terminal and at least three guide terminals on a device under test (DUT) PCB, wherein the at least one biased pin is recessed relative to the fixed guide pins and applying the TDR probe to the DUT PCB such that the fixed pins align with the guide terminals and permit the at least one recessed biased pin to contact the signal terminal.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a diagram showing an exemplary time domain reflectometry (TDR) test site on a device-under-test (DUT) printed circuit board (PCB) for use with conventional probes.

FIG. 2 is a diagram showing an exemplary DUT PCB TDR test site for use with a high-frequency tripod TDR probe according to the present principles.

FIG. 3 is a diagram showing an exemplary high-frequency tripod TDR probe according to the present principles.

FIG. 4 is a graph that shows insertion/return loss associated with frequency for an impedance controlled tripod TDR probe design.

FIG. 5 is a diagram showing an exemplary printed circuit board (PCB) adaptor layout for a probe according to the present principles.

FIG. 6 is a three-dimensional view of the PCB adaptor for a probe according to the present principles.

FIG. 7 is a block/flow diagram showing a method for performing high-frequency TDR using a probe and PCB according to the present principles.

FIG. 8 is a diagram showing an exemplary TDR test system according to the present principles.

FIG. 9 is a graph depicting an exemplary TDR measurement.

### DETAILED DESCRIPTION OF PREFERRED EMBODIMENTS

When a signal propagates through a transmission line, changes in impedance can interfere with propagation by attenuating the signal and introducing reflections. As such, the measurement of impedance is an important step in testing. Time domain reflectometry (TDR) helps accomplish this. TDR sends a pulse through the transmission line and measures reflected waveforms that result from impedance changes. Because the speed of propagation is generally stable through a transmission line, measuring the time between pulse and reflection provides information regarding the location of the impedance change. However, the usefulness of TDR can be limited at high frequencies due to limitations in the tools used.

The size of an impedance discontinuity can be determined from the amplitude of a reflected signal in TDR. Furthermore, the distance of the reflecting impedance from the signal launch can be determined from the time that a pulse takes to return if the transmission properties of the medium are known. For example, a coaxial cable formed with a solid polyethylene dielectric has a wave velocity of 66% the speed of light in a vacuum.

This technique is limited in particular by the “rise time” of the system, which refers to the amount of time it takes a signal to change from a specified low value to a specified high value (or vice-versa for the equivalent “fall times”). For example, in a square wave, there will be an imperfection in the signal due to the limitations of the equipment, such that there will be a measurable ramp in the signal rather than an ideal step. Using high-frequency equipment decreases this rise time and improves the accuracy of TDR measurements as faster rise times allow one to examine higher frequency behavior and to improve the spatial resolution of the measurement. A high-frequency test signal will find transmission faults that may be invisible at lower frequencies.

For example, if a pure resistive load is placed at the output of a reflectometer and a step signal is applied, a step signal will be observed in the measurement with its height being a function of the resistance. The magnitude of the reflection caused by the resistive load may be expressed as a function of the input signal as given by:

$$ρ = \frac{{R}_{L} - {Z}_{0}}{{R}_{L} + {Z}_{0}} .$$

R_{L} represents the resistance of the resistive load and Z₀ represents the characteristic impedance of the transmission line. A discontinuity can be interpreted as a termination impedance and substituted for R_{L}. In this way, using the measured reflected magnitude, a known line impedance, and a known speed of transmission in the transmission medium, an operator is able to determine both the location and size of an impedance defect in the medium. Some impedances are dependent on frequency, such that faults which are invisible at low frequencies can become very large at higher frequencies. High-frequency testing equipment is needed to determine the size and locations of such high-frequency faults.

Exemplary applications for TDR include preventative maintenance in telecommunication lines, where operators can detect points of growing resistance as transmission lines corrode. TDR is also useful in determining the presence and location of wiretaps. For example, the slight change in line impedance caused by the introduction of a tap or splice in a line will show up as a reflected signal in a TDR measurement. In the present case, TDR may be used, for example, to find unsoldered pins and short circuits in a printed circuit board (PCB). In this fashion, TDR may be used as a non-destructive technique to find defects in semiconductor device packages.

High-frequency signals are affected by changes in impedance that occur at higher frequencies than those that affect low-frequency signals. Impedances of transmission lines and other components, such as connectors, tend to deviate more from their ideal values at higher frequencies than at low frequencies. Therefore, high frequency data suffers greater distortions than would be inferred from TDR measurements limited only to the lower frequencies. For this reason, a short rise time (or “fast edge”) in the TDR's step function is needed to test in systems that use high-frequencies. Toward this end, the present principles provide high-frequency probes and launches to enable high-frequency reflectometry in an efficient, easy-to-use manner.

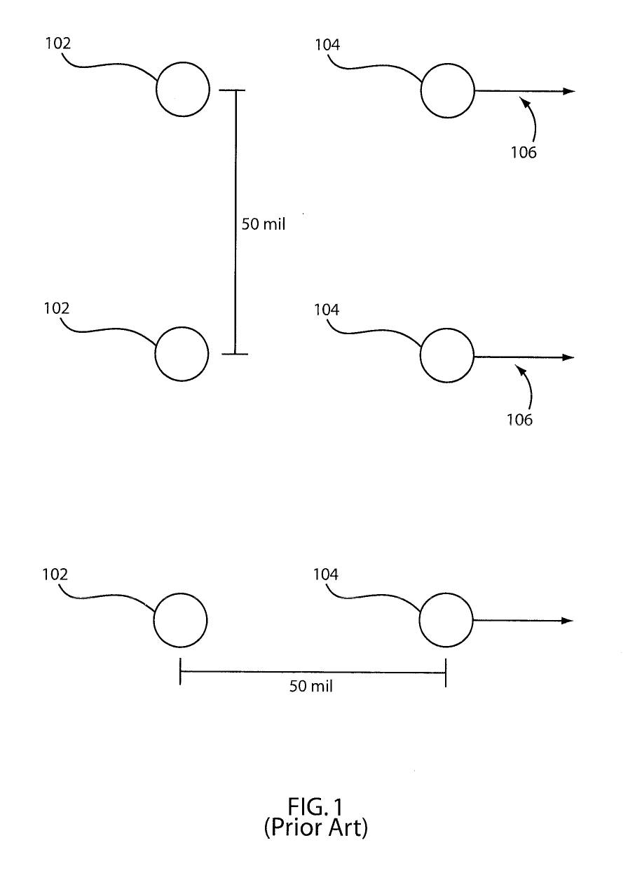

Referring now to the drawings in which like numerals represent the same or similar elements and initially to FIG. 1, a typical TDR test site is shown. For the sake of robustness, vias are typically drilled with a diameter on the order of 15-20 mils on a 50 mil pitch. This pitch is sufficiently large that an unskilled operator can simultaneously touch the signal pad 104 and the ground pad 102 for long enough to activate a TDR measurement along a transmission line 106. The large via pitch and diameter needed for such a probe place significant constraints on the bandwidth of the launch shown in FIG. 1. Typical bandwidths of several GHz can be obtained, but this is variable and dependent on the depth of the signal layer in the PCB due to via stub effects. Ultimately the pitch size and the probe design put an effective upper limit on the frequencies that may be tested using such systems.

Industry standards such as IPC 2.5.5.7 which define how to measure the “Characteristic Impedance of Lines on Printed Boards by TDR” are limited in terms of frequency bandwidth by the constraints imposed by low cost rugged probes that can be used by untrained manufacturing personnel to quickly measure device-under-test (DUT) PCB test coupons in a production setting. These probes are mechanically rugged and should not require time consuming alignment (e.g., use of microscopes). These requirements have led to the design of test coupons and probes that are physically large and, due to resulting electrical parasitics, do not possess the performance needed to test at higher bandwidths called for by high speed designs (e.g., 10 Gb/s and above).

The present principles provide a high speed probe structure with tripod stabilization that is able to launch much faster signals into internal PCB traces. When used in conjunction with backdrilling and/or cavity milling, all internal signal layers can be reached within a PCB. Using such a low cost probe and launch structure will enable not only line impedance but also line loss measurements to extend beyond 10 GHz instead of the 1 GHz limits of current structures. The present principles make use of miniaturized spring-loaded pins to construct a probe that, when used in conjunction with a recommended test coupon layout on the DUT PCB, can produce TDR and time domain transmission results with fidelity sufficient to cover 10 GHz requirements.

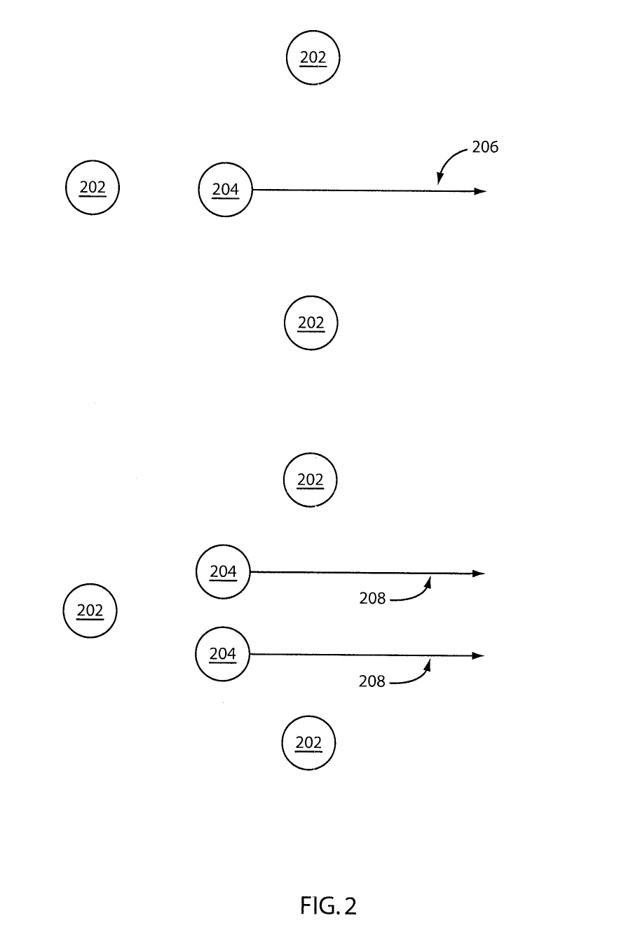

Referring now to FIG. 2, two launch layout embodiments using tripod stabilization are illustratively shown in accordance with one embodiment. In this illustrative embodiment, three ground vias 202 are arranged in a triangle on a PCB around a signal via 204 connected to a single-ended transmission line 206. The ground vias 202 are holes formed in the PCB by, e.g., drilling. In another second embodiment, the three ground vias 202 are arranged in a triangle around two signal vias 204, said vias being connected in turn to differential transmission line 208. Although a triangular arrangement of the ground vias 202 is discussed herein, it is contemplated that a greater number of ground vias 202 may be used, and that the ground vias 202 may be arranged in alternative patterns, the “tripod” nomenclature notwithstanding. The exemplary embodiments use a tripod configuration with three ground vias because three points uniquely define a plane, thereby providing a simple, yet stable, geometry. Furthermore, although only embodiments having one or two signal vias 204 are shown, it is contemplated that any number of signal vias 204 may be used.

It is furthermore contemplated that the holes 202 may simply be recessed areas on the PCB, allowing the pins of the probe to align with them. Additionally, it is contemplated that fewer than all of the holes 202 may be connected to a true ground.

Referring now to FIG. 3, a probe using tripod stabilization is illustratively shown. Three ground pins 302 are arranged in an equilateral triangle. As noted above, it is also contemplated that other triangular configurations, such as an isosceles triangle, or even non-triangular configurations such as quadrilaterals, may be used. The ground pins 302 have a wide conical tip, allowing the probe to self-center in the ground vias 202 of FIG. 2. Although conical tips are used for the purpose of illustration, this is not intended to be limiting. It is also contemplated that flat tips, spherical tips, etc., may be employed.

These ground pins 302 are fixed in that they do not retract upon seating. A spring-loaded pin 304 is disposed in the centroid of the equilateral triangle. The spring-loaded pin 304 is small, for example, 10-12 mils in diameter. Use of small pins 304 allow for smaller diameter signal vias in the DUT PCB, with a higher associated bandwidth. Spring loading of this pin provides for vertical mechanical compliance of the probe assembly to avoid damage to the fragile pin 304.

Small-diameter pins 304 need to be accurately aligned to make effective contact with signal vias. When the probe is then lowered to make contact, the conical tips 302 guide the fragile signal pin 304 to the correct location. By aligning the guiding ground pins 302 with ground vias 202, the probe is centered and the signal pin 304 is accurately aligned with its contact point.

The ground vias may be formed by, e.g., a drilling or milling operation. The conical shapes of the tips 302 guide the apex of the cones into the drilled holes of the ground vias and provide a self-centering effect. The tips of the conical probes 302 travel a small distance beyond the plane of the PCB, which allows the recessed signal tip 304 to make contact with the signal via pad 204 on the surface. The tripod configuration of the robust ground pins 302 forms a mechanical cage which prevents damage to the central pin 304 when the probe is not engaged with a PCB. Because the signal pin 304 is mechanically biased with, e.g., a spring, it can compress after making contact with the PCB. This helps prevent damage to the signal pin 304.

The probe design shown in FIG. 3 is open and allows the operator to see the connection. Furthermore, the present principles do not need high-precision positioners, allowing for intuitive, low-cost and low-effort use. The sturdy ground pins 302 provide robust protection of the smaller spring-loaded pins 304, preventing damage to the inner pins 304 in use as well as when the probe is not being used. Furthermore, although the ground pins 302 are shown as having the same length, it is also contemplated that the pins may have different lengths with respect to one another to facilitate access to potentially difficult to reach PCBs. The length and positioning of ground pins 302 may further be made adjustable to accommodate PCBs of different dimensions. It is contemplated that one, some, or all of the ground pins 302 may connect to grounded terminals. It is further contemplated that one or more of the pins 302 may have alternative functions, allowing for, e.g., testing of ground terminals to ensure a shared ground voltage.

To provide for high bandwidths, e.g., about 10 GHz or higher, signal vias 204 may be backdrilled for thicker PCB stackups, so that the residual stub is preferably less than 20 mils in length. Additionally, the spring-loaded pins 304 should transition into an impedance controlled structure and should be positioned so that the coupling between the ground 302 and signal pins 304 continue this controlled impedance structure.

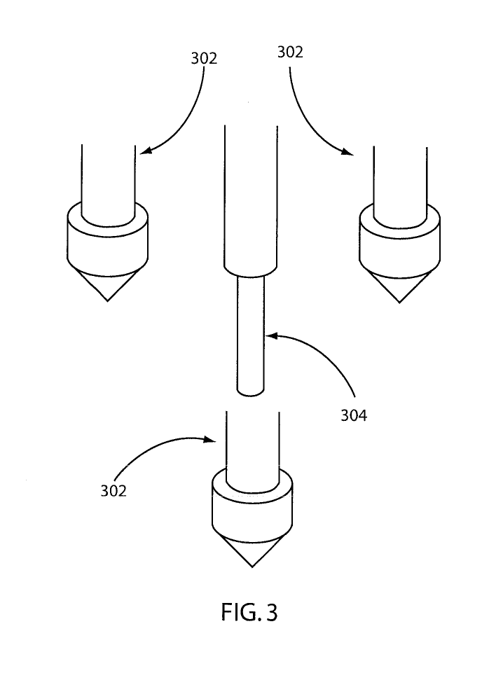

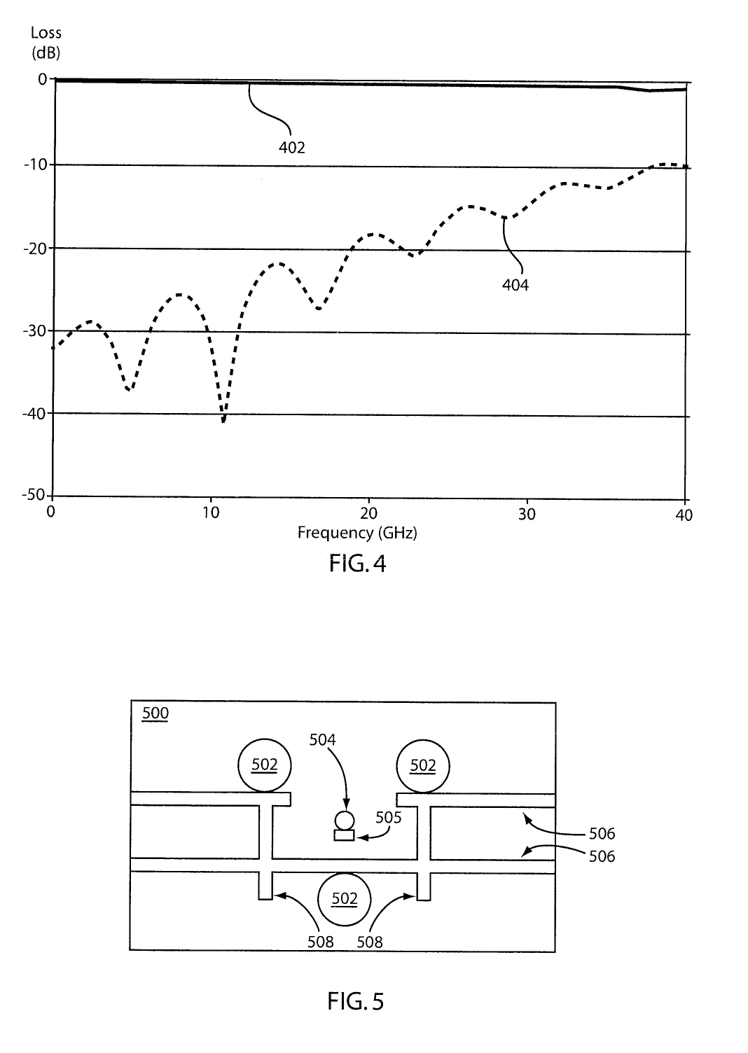

Referring now to FIG. 4, a finite element electromagnetic simulation is shown that optimizes the diameters and radial spacing of the spring loaded signal pin 304 and the three ground pins 302 to produce a 50-ohm impedance which is a common transmission line impedance value. Different impedance levels may need adjustment to the diameters and/or radial spacings of these pins. For a given diameter of the ground pins 302, a separation between the pins needs to be established to yield the desired impedance. Due to the three-dimensional nature of the fields involved, this may be accomplished with a finite element field solver. While there may be analytical formulas for an idealized two-dimensional geometry, such formulas may not be accurate enough when including the impedance controlled structure (PCB adaptor) that the pins attach to and the high-speed probe launch on the DUT PCB. The solid line 402 on the graph represents insertion loss in decibels The dashed line 404 shows a reflection or return loss. It should be less than 20 dB over the frequency content of the signal.

Referring now to FIG. 5, a cross-sectional view of a stripline PCB adaptor design for the tripod TDR probe having a single-ended transmission line is shown. Ground reference planes 506 are connected by ground vias 508. A stripline trace 505 connects to signal pin 504. The PCB stripline configuration shown in FIG. 5 affords very high bandwidth and good impedance control. Cavities are formed, e.g. by milling, at appropriate locations and depths to afford solder access to the spring-loaded pin shafts 304. The distal ends of stripline 504 and ground reference planes 506 can be designed to accommodate either an edge or a vertical coaxial connector launch to provide a standardized interface to TDR step generator equipment. In this fashion, the triangular arrangement of pins described above with respect to FIG. 3 can be formed, providing for easy operation of the probe while protecting the signal pin 304 from damage.

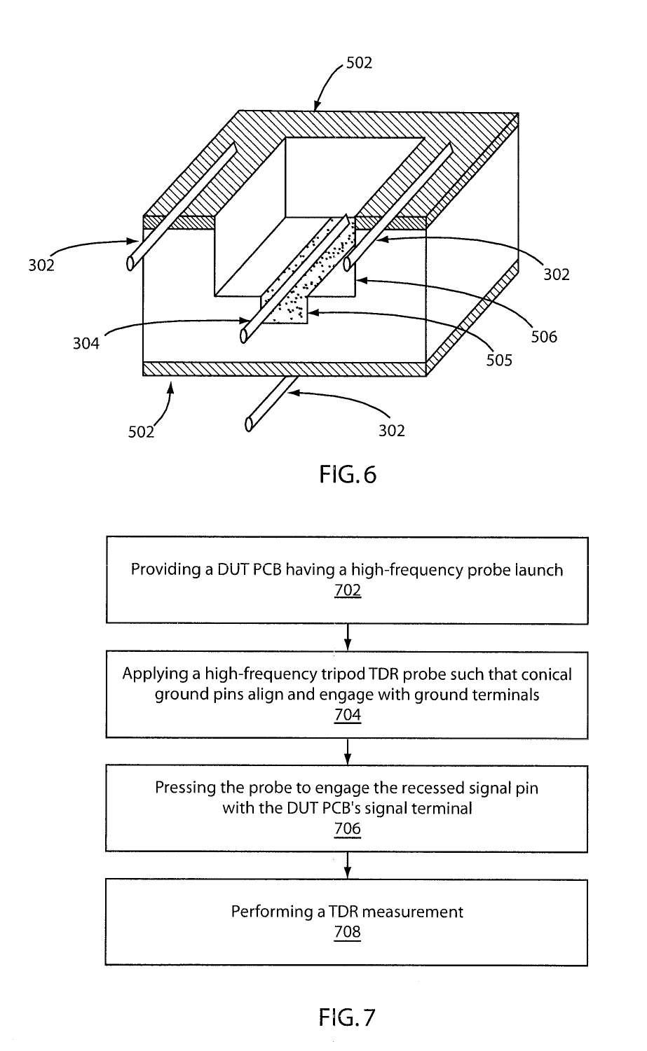

Referring now to FIG. 6, a three-dimensional view of the stripline PCB adaptor design of the probe is shown. The probe PCB adaptor transitions from a common coaxial interface, for example an “SMA” or “K” connector, to the pins of the tripod TDR probe. One configuration that leads to a low cost, manufacturable implementation is to solder the probe pins to a stripline fabricated in the probe PCB 500. The ground pins 302 are connected to the reference ground planes 502 of the stripline and the spring loaded pin 304 is connected to the stripline signal trace 505 after a cavity 506 is milled to provide mechanical access from the stripline printed circuit board surface. A cavity can be prepared on the distal surface in a similar fashion to provide a transition to an edge launched coaxial connector.

Referring now to FIG. 7, a method for performing a high-frequency TDR measurement according to the present principles is shown. Block 702 provides a DUT PCB having a TDR probe launch as described, e.g., in FIG. 2 above. Block 704 applies a high-frequency TDR probe, such as that shown, e.g., in FIGS. 3, 5 and 6 above, to the probe launch such that the conical ground pins (e.g., 302) align and engage with ground terminals (e.g., 202). Applying the probe should be a simple process, due to the probe design described above, such that little training is necessary and the risk of accidental damage to the probe or the DUT PCB is low.

The conical ground pins pass through the top surface plane of the DUT PCB, allowing the recessed signal pin (e.g., 304) to engage with the DUT PCB's signal terminal (e.g., 204) at block 706. This forms an operative connection between the probe and the DUT PCB, allowing the probe to perform a high-frequency TDR measurement at block 708. The TDR measurement may include applying a high-frequency signal to the signal terminal(s) 204 and measuring reflected signals, allowing the operator to determine the position and magnitude of line impedance changes.

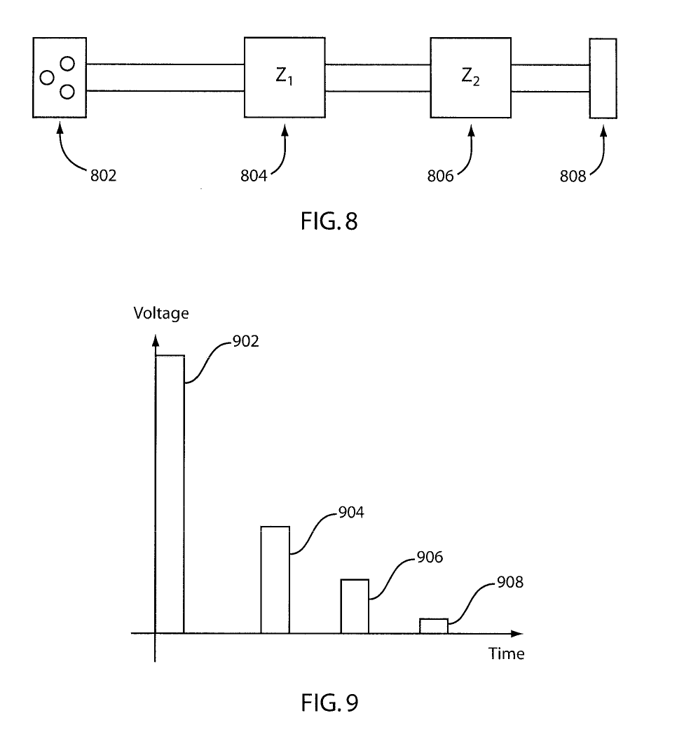

Referring now to FIG. 8, an exemplary TDR arrangement is shown. A TDR launch 802 according to the present principles is disposed at the end of a pair of differential transmission lines. The launch 802 is configured to be compatible with the probe designs shown in, e.g., FIGS. 3, 5, and 6. For the purposes of this discussion, assume that the transmission lines are perfectly terminated at terminator 808, such that no reflections are produced when a signal reaches the terminator 808. In between, there are two points, 804 and 806, which have impedance changes Z₁ and Z₂ respectively. When a pulse is provided at launch 802, it travels down the transmission lines without change until it reaches Z₁ block 804. At this point, a partial reflection is generated that returns to the launch 802. The remainder of the signal continues until it reaches Z₂ block 806. Again, a partial reflection is generated, while the remainder of the signal continues to the perfect terminator 808, at which point the signal leaves the system. The partial reflection from Z₂ block 806 returns to block Z₁ block 804, at which point another partial reflection is generated and the bulk of the signal returns to the launch 802. There will be a remainder signal echoing back and forth between blocks 804 and 806, producing signals of decreasing size at the launch 802 until it completely dissipates.

The impedances 804 and 806 may be frequency-sensitive. For example, an inductive impedance may be characterized as

Z=jωL,

where j is \sqrt{−1}, ω is the frequency, and L is the inductance. At low frequencies, an inductive impedance will be relatively small and will have little effect on the transmission of signals. As frequencies increase beyond, for example, 10 GHz, the impedance increases proportionally and may become very significant. This means that low-inductance features, which were undetectable and harmless at low frequencies, should be tested for using high-frequency test signals. In such systems, the present principles are highly advantageous in providing TDR at frequencies in such a high operating range.

Referring now to FIG. 9, an exemplary oscilloscope measurement is shown that describes the TDR measurements at launch 802. Pulse 902 represents the initial signal pulse generated by a TDR probe at launch 802. Pulse 904 represents a reflection from Z₁ block 804, where the fact that the pulse is positive indicates that the reflection was caused by an increase in impedance. The diminished size of pulse 904 represents the fact that much of the original pulse 902 continued onward pas the impedance discontinuity. A negative reflection would have indicated a decrease in impedance. Pulse 906 is the reflection from Z₂ block 806, the pulse 906 itself having been diminished by passing through impedance change Z₁ block 804 on the return trip. Pulse 908 represents an echo, where the partial reflection of pulse 906 at block 804 is itself partially reflected at block 806 before being measured at the launch 802.

As noted above, the size and timing of the pulses allow an operator to precisely determine the location and severity of faults in the line. Echo reflections, such as 908, can be detected and removed by noting their periodicity and rapidly diminishing strength. This allows for precise determination of the locations of impedance changes as well as a filtering of information which might otherwise be mistakenly interpreted as such changes.

Having described preferred embodiments of a system and method for high performance time domain reflectometry (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A probe, comprising:
at least one mechanically biased pin to connect to at least one contact point; and
at least three fixed guide pins arranged about the at least one biased pin to facilitate alignment of said at least one biased pin by first engaging at least one grounded area, such that the at least one mechanically biased pin is guided to the at least one contact point.

2. The probe of claim 1, wherein the at least three fixed guide pins are arranged in a tripod arrangement.

3. The probe of claim 2, wherein the tripod arrangement of the fixed guide pins includes pin locations at apexes of an equilateral triangle.

4. The probe of claim 1, comprising four fixed guide pins arranged in a quadrupedal arrangement.

5. The probe of claim 1, wherein the fixed guide pins have conical tips.

6. The probe of claim 1, wherein the at least one biased pin is moveably mounted and wherein the at least one biased pin is recessed from the tips of the fixed guide pins.

7. The probe of claim 1, wherein the at least one biased pin transitions into an impedance controlled structure when connected to the at least one contact point.

8. The probe of claim 7, wherein the biased pins are positioned such that coupling between the fixed guide pins and the at least one biased pin maintain the impedance controlled structure when the at least one biased pin is connected to the at least one contact point.

9. The probe of claim 1, wherein the fixed guide pins have different lengths with respect to one another.

10. The probe of claim 1, further comprising a stripline printed circuit board (PCB) with the at least one biased pin and the at least three guide pins being coupled to the stripline PCB.

11. The probe of claim 10, further comprising cavities formed in the stripline PCB at locations and depths to permit connection to the probe pins.

12. A high-speed probe launch, comprising:
a printed circuit board (PCB) configured to provide access to a probe, including:
at least one signal terminal connected to at least one signal via; and
at least three guide terminals arranged around the at least one signal terminal, wherein at least one of said guide terminals is connected to at least one ground via.

13. The probe launch of claim 12, wherein the PCB comprises three guide terminals arranged triangularly.

14. The probe launch of claim 12, wherein the PCB includes a stripline configuration that provides an impedance control structure.

15. The probe launch of claim 12, wherein a distal end of the stripline may accommodate one of an edge and a vertical coaxial connector launch.

16. The probe launch of claim 12, wherein the PCB comprises one signal terminal connected to a single-ended transmission line.

17. The probe launch of claim 12, wherein the PCB comprises two signal terminals connected to differential transmission lines.

18. A time domain reflectometry system, comprising:
a printed circuit board (PCB) comprising:
at least one signal terminal connected to at least one signal via; and
at least three guide terminals arranged around the at least one high-frequency signal terminal, wherein at least one of said guide terminals is connected to at least one ground via; and
a probe comprising:
at least one biased pin to contact the at least one signal terminal; and
at least three fixed guide pins arranged about the at least one biased pin to facilitate alignment of said at least one biased pin by first engaging at least one guide terminal area, such that the at least one mechanically biased pin is guided to the at least one contact point.

19. The system of claim 18, wherein the pins of the probe are disposed so as to correspond with the terminals of the PCB.

20. The system of claim 18, wherein the probe further comprises a stripline PCB with the at least one biased pin and the at least three guide pins being coupled to the stripline PCB.

21. The system of claim 20, wherein cavities are formed in the stripline PCB at locations and depths to permit connection to the probe pins.

22. A method for time domain reflectometry (TDR), comprising:
providing a TDR probe having at least one biased pin and at least three fixed guide pins to correspond to at least one signal terminal and at least three guide terminals on a device under test (DUT) printed circuit board (PCB), wherein the at least one biased pin is recessed relative to the fixed guide pins; and
applying the TDR probe to the DUT PCB such that the fixed pins align with the guide terminals and permit the at least one recessed biased pin to contact the signal terminal.

23. The method of claim 22, further comprising applying a signal to the signal terminal and measuring signal reflections.

24. The method of claim 23, wherein the signal has a frequency of at least 10 GHz.

25. The method of claim 23, further comprising determining a location and size of an impedance change based on the measured signal reflections.
